(19) United States
(12) Patent Application Publication
(10) Pub. No.: US 2010/0047447 A1
(43) Pub. Date: Feb. 25, 2010

(54) MULTIPLE SUBSTRATE ITEM HOLDER AND REACTOR

(76) Inventor: Robert C. Cook, Santa Rosa, CA (US)

Correspondence Address: BERKELEY LAW & TECHNOLOGY GROUP, LLP, 17933 NW Evergreen Parkway, Suite 250, BEAVERTON, OR, 97006, US

(21) Appl. No.: 12/197,587

(22) Filed: Aug. 25, 2008

(51) Int. Cl. C23C 16/00; B05C 13/00; B05C 9/02; B65H 1/00; B05C 11/00

(52) U.S. Cl. 427/248.1; 118/500; 118/728; 118/708; 414/806

(57) ABSTRACT

Methods, apparatuses and systems are provided that may be used in performing controlled environment processes on substrate items within in at least one chamber A plurality of substrate items may be arranged at each of a plurality of horizontal levels within a vertically oriented stack of a substrate item holding assembly and moved into a reactor chamber and/or other like chamber and processed.

### BACKGROUND

1. Field

The subject matter disclosed herein relates generally to methods, apparatuses and systems for use in performing controlled environment processes on substrate items within in at least one chamber.

2. Information

There are several types of reaction chamber designs in use for epitaxial (EPI) layer growth of various materials, chemical vapor deposition (CVD), atomic layer deposition (ALD) and/or other like film growth and deposition techniques. Similar reactor designs are used for other processes such as, oxidation, etching, etc, Such designs tend to fall into two basic categories, namely, single wafer reactors and batch reactors. Single wafer reactors may be useful for very thin films where the process times are relatively short, e.g., on the order of seconds to a couple of minutes. For longer process times, e.g., which may needed for thicker deposited films and/or due to slower material growth rates, e.g. ALD processes, the ability to process multiple wafers at the same time may be more beneficial given increased throughput and reduced processing costs, etc. Some batch reactors, however, may be inefficient due to there resulting increase in chamber size and may waste materials that do not reach effective proximity to the wafers, which may actually increase costs.

### BRIEF DESCRIPTION OF DRAWINGS

Non-limiting and non-exhaustive aspects are described with reference to the following figures, wherein like reference numerals refer to like parts throughout the various figures unless otherwise specified.

FIG. 1 is a block diagram illustrating selected portions of an exemplary system that may be used for depositing and/or growing thin films or other like layers of material(s) on substrate items in a controlled environment in accordance with an implementation.

FIG. 2 is a cross-sectional side-view of selected portions of an exemplary substrate item holding assembly that may be used in the system of FIG. 1, for example, to hold a plurality of substrate items at a plurality of horizontal levels within a vertical stack of levels.

FIG. 3 is a flow diagram illustrating an exemplary method that may be implemented, for example, with respect to the system of FIG. 1.

FIG. 4 is a cross-sectional top-view of selected portions of an example reactor apparatus, having a substrate item holding assembly therein, that may be used in the system of FIG. 1, for example.

FIG. 5 is a cross-sectional side-view of selected portions of the example reactor apparatus and substrate item holding assembly of FIG. 4.

FIG. 6 is a cross-sectional top-view of selected portions of another example reactor apparatus, having a substrate item holding assembly therein, that may be used in the system of FIG. 1, for example.

FIGS. 7A-D are top-view diagrams illustrating exemplary arrangements of a plurality of different substrate items arranged with respect to an exemplary dividing member of a substrate item holding assembly that may be used in the system of FIG. 1, for example.

FIG. 8A is a top-view diagram illustrating an exemplary arrangement of a plurality of substrate item supports on an exemplary dividing member of a substrate item holding assembly that may be used in the system of FIG. 1, for example.

FIG. 8B is a top-view diagram illustrating another exemplary arrangement of a plurality of substrate item supports of a substrate item holding assembly supporting substrate items as may be used in the system of FIG. 1, for example.

FIGS. 9-11 are close-up cross-sectional side-views of different selected portions of an example reactor apparatus that may be used in the system of FIG. 1, for example.

FIGS. 12 and 13 are cross-sectional side-views of selected portions of an example apparatus having a reactor chamber and a second chamber that may be used in the system of FIG. 1, for example.

FIG. 14 is a cross-sectional top-view of selected portions of the example apparatus of FIG. 13 at cut-line A.

FIG. 15 is a cross-sectional side-view of selected portions of another example apparatus having a reactor chamber and a second chamber that may be used in the system of FIG. 1, for example.

FIG. 16 is a cross-sectional top-view of selected portions of the example apparatus of FIG. 15.

FIG. 17 is a cross-sectional side-view of selected portions of yet another example apparatus having a reactor chamber and at least two other chambers that may be used in the system of FIG. 1, for example.

FIG. 18 is a cross-sectional side-view of selected portions of another example reactor apparatus and substrate item holding assembly, for example, of FIG. 4.

### DETAILED DESCRIPTION

The methods, apparatuses and systems provided herein may be implemented for economically depositing and/or growing thin films or other like layers of materials on substrate items and/or other films or layers thereon in a controlled environment reactor. By way of example but not limitation, the techniques provided herein may be implemented in systems that provide vapor phase epitaxy (VPE), chemical vapor deposition (CVD), atomic layer deposition (ALD), and/or other like processes which may be performed, at least in part, using reaction chambers or vessels having control of temperature, pressure, and/or gas mass flow rates. This type of chamber may also be used for purely thermal annealing or heat-treating or for chemical surface conditioning/cleaning or etching of native oxide with HF vapors or for remote plasma reactive ion etching and the boat could be RF energized for PECVD and plasma etching and other processes requiring controlled environment.

By way of example but not limitation, the techniques provided herein may be implemented using a reactor apparatus having a reaction chamber that receives a substrate item holding assembly. In certain example implementations, the substrate item holding assembly may take the form of a multiple wafer holding “boat” that holds a plurality of wafers in horizontal layers which are arranged in a stack. Such a wafer holding boat may, for example, be constructed, at least in part, using one or more thermally conductive materials, thermally insulating materials, and/or a combination thereof. The size and geometry of such a wafer holding boat may be selected to allow the placement multiple wafers on the same plane or level, and to have one or more levels arranged between dividing members (e.g., disks, susceptors, etc.). In certain implementations, one or more dividing members may, for example, be constructed, at least in part, using thermally conductive materials. A plurality of substrate item supports may be provided to support or otherwise hold the substrate items (wafers in this example) at the various levels within the stack. In certain example implementations the substrate item supports may provide structural support for the substrate item holding assembly (wafer boat, in this example). Here, the resulting stack wafers as held in the wafer boat may then be placed within a reactor chamber or other like chamber.

As used herein the term “substrate item” is intended to represent any item onto which and/or with which one or more films and/or layers of one or more materials may be established (e.g., deposited, grown, etc.), and/or removed therefrom, and/or modified or otherwise processed in some manner. Such a “substrate item” may itself be comprised of one or more materials, films, layers, that form various features, openings, etc. Such a “substrate item” may itself have portions that are planar, substantially planar, or non-planar in shape. By way of example but not limitation, certain substrate items may be associated with semiconductor circuits, solar panels, hard disk drive platters, display devices, optical lens, and/or the like.

In certain implementations, the substrate items placed on a level and/or within the stack of the substrate holding assembly may be of the same type, size, and/or shape. In certain other example implementations, different types, sizes, and/or shapes of substrate items may be placed on the same or different levels within the stack of the substrate item holding assembly.

Attention is now drawn to FIG. 1, which is a block diagram illustrating selected portions an exemplary system 100 that may be used for depositing and/or growing thin films and/or other like layers of material(s) 209 on at least one exposed surface of a substrate item 208.

System 100 may include a housing assembly 104 providing a sealable reaction chamber 106 to receive a substrate item holding assembly 102. Housing assembly 104 may, for example, include at least one liner member 116, a top member 120, a bottom member 122, and at least one sidewall member 124. As illustrated in FIG. 1, liner member 116 and sidewall member 124 may be physically separated, at least in part, to establish a gap region 140.

Various process support assemblies may be coupled to various portions of housing assembly 104. For example, a temperature control assembly 108 may be provided to establish a temperature within reaction chamber 106, a gas supply assembly 110 may be provided to introduce gaseous material(s) 112 into reaction chamber 106, a gas exhaust assembly 114 may be provided to remove gaseous material(s) from within reaction chamber 106, and/or one or more transport assemblies 132 may be provided to move substrate item holding assembly 102, and/or one or more substrate item 208.

Temperature control assembly 108 is intended to represent one or more mechanisms that may be implemented using one or more temperature (heating and/or cooling) techniques. For example, inductive heating techniques, radiant heating techniques, convection heating techniques, and/or a combination thereof may be implemented. Thus, those skilled in the art will recognize that temperature control assembly 108 may, depending on design, include various subassemblies (not shown) such as, e.g., temperature inducing elements, coils, antennas, lamps, sources, connections, controls, circuits, feedback mechanisms, temperature probes, power sources, thermal bodies/masses, insulation, supports, etc.

Gas supply assembly 110 is intended to represent one or more mechanisms that may be implemented to selectively introduce gaseous material(s) 112 into reaction chamber 106. As used herein, gaseous materials is intended to represent materials that are in a gas state and/or otherwise suspended or provided via other materials that are in a gas state. For example, gaseous material(s) 112 may include one or more chemical elements, compounds, reactants, and/or the like which may be selectively provided in accordance with a process recipe to establish one or more layers of material(s) 209. Thus, those skilled in the art will recognize that gas supply assembly 110 may, depending on design, include various subassemblies (not shown) such as, e.g., one or more material sources, tanks, pumps, valves, meters, sensors, tubes, pipes, connections, controls, circuits, power supplies, supports, etc.

Gas exhaust assembly 114 is intended to represent one or more mechanisms that may be implemented to selectively remove gaseous material(s) from within reaction chamber 106. Those skilled in the art will recognize therefore that gas exhaust assembly 114 may, depending on design, include various subassemblies (not shown) such as, e.g., one or more pumps, material receptacles, valves, meters, sensors, tubes, pipes, connections, controls, circuits, power supplies, supports, etc.

Transport assemblies 132 is intended to represent one or more mechanisms that may be implemented to selectively physically move in some manner substrate item holding assembly 102, and/or one or more substrate items 208. For example, a transport assembly 132 may be provided to move substrate item holding assembly 102 into and/or out of reaction chamber 106. For example, a transport assembly 132 may be provided to rotate substrate item holding assembly 102. For example, a transport assembly 132 may be provided to move a substrate item 208 into and/or out of substrate item holding assembly 102. Consequently, those skilled in the art will recognize therefore that transport assemblies 132 may, depending on design, include various subassemblies (not shown) such as, e.g., motors, actuators, arms, robotic mechanisms, robotic end-effectors for moving one or more substrate items, rails, doors, cameras, sensors, scanners, pneumatics, hydraulics, levers, valves, switches, tubes, pipes, connections, controls, circuits, supports, etc.

In certain implementations, a pressure controlling assembly 134 may be provided to establish a desired atmosphere in gap region 140, for example, using at least one gas 136. For example, an inert gas may be provided within gap region 140 to help prevent gaseous materials within reaction chamber 106 from entering (e.g., leaking) into the gap region. Those skilled in the art will recognize that, in certain implementations pressure controlling assembly 134 may be part of gas supply assembly 110.

Pressure controlling assembly 134 and/or gas supply assembly 110 may, for example, also include an electromagnetic energy source 138 and/or the like to further establish (e.g., strike) plasma 142 within reaction chamber 106. Plasma 142 may, for example, be used for cleaning (e.g., stripping) the substrate item holding assembly 102 and/or exposed surfaces within reaction chamber 106. Plasma 142 may, for example, be established in gap region 140 should there be any accumulated deposit and/or dust from gas phase reaction due to unwanted penetration of the gaseous materials into gap region 140. Those skilled in the art will recognize that pressure controlling assembly 134 may, depending on design, include various subassemblies (not shown) such as those mentioned above with regard to gas supply assembly 110 and/or gas exhaust assembly 114, and/or other like subassemblies.

As further illustrated the various assemblies that support the processing operations may be operatively controlled or otherwise further enabled through a process control assembly 130, which may for example include one or more computers, communication devices, networks, user interfaces, and/or computer implementable instructions or the like opertively associated therewith.

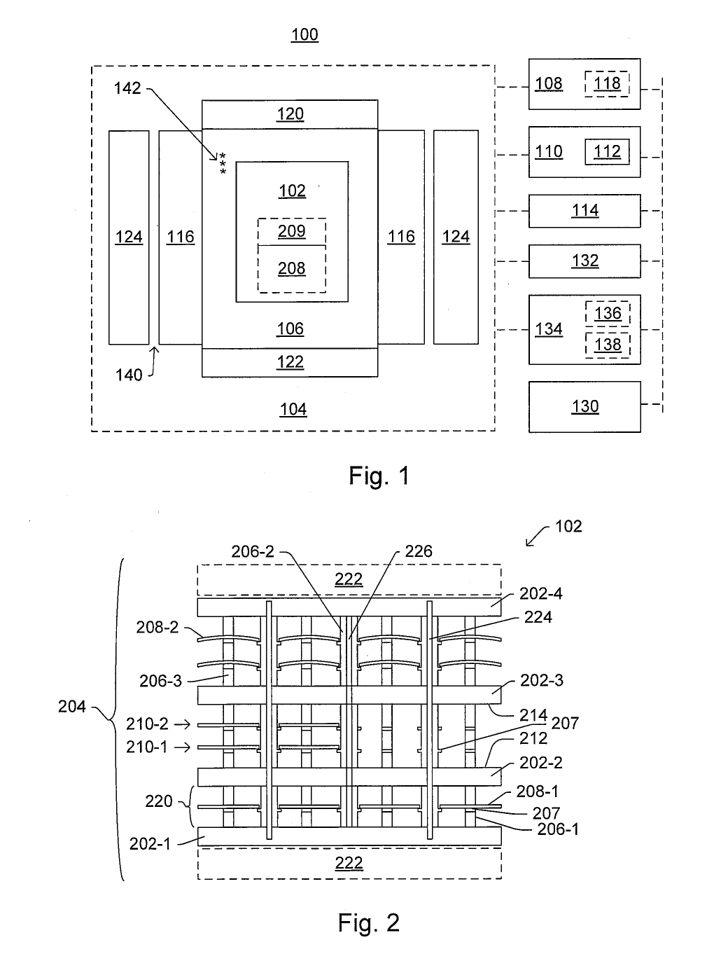

Attention is drawn next to FIG. 2, which is a cross-sectional side-view of selected portions of an exemplary substrate item holding assembly 102 that may be used in system 100, for example, to hold a plurality of substrate items 208 at a plurality of horizontal levels within a vertical stack of levels 204. Exemplary substrate item holding assembly 102 is intended only to illustrate certain features that may be implemented in various designs and is not intended to limit claimed subject matter.

With this in mind, substrate item holding assembly 102 as illustrated may include a plurality of dividing members 202, which are represented in this example by dividing members 202-1, 202-2, 202-3, and 202-4. In this example, at least one connecting member 224 is illustrated as connecting the dividing members together to form stack 204. To provide such structure, connecting member 224 may be fixedly, compressively, and/or otherwise connected in some manner to one or more of the dividing members. Those skilled in the art will recognize that in other implementations one or more of connecting member(s) 224 may connect to and/or pass through all, some, or none of the dividing members. Here, for illustrative purposes connecting member 224 is shown as being attached to at least dividing members 202-1 and 202-4 to provide support for the stack, while also passing through dividing members 202-2 and 202-3. Additionally, in this example, the labeled connecting member 224 is shown as passing through certain substrate item supports 206 that may be provided between dividing members 202. An example substrate item support 206-2 is illustrated without a connecting member passing through it to illustrate that an opening 226 may be provided through which a connecting member may pass.

A plurality of example substrate item supports 206 are shown in FIG. 2. In this example implementation substrate item supports 206 may be configured to add addition structure to stack 204 by establishing a corresponding vertical space 220 and also one or more horizontal substrate levels between adjacent dividing members 202. For example, substrate item support 206-1 may be designed to provide support within stack 204 by establishing a space 220 between dividing members 202-1 and 202-2. In certain implementations, substrate item support 206-1 may or may not include an opening for a connecting member to pass through. Also, as illustrated, example substrate item support 206-1 may be designed with a ledge feature 207 (e.g., a protrusion, an indentation, and/or the like) to provide a support surface for a single horizontal substrate item level for a plurality of substrate items (e.g., including labeled substrate item 208-1). Certain example substrate item supports, such as 206-2, may be designed with a plurality of vertically spaced apart ledge features 207 that may be designed to provide support surfaces for a plurality of horizontal substrate item levels. Certain example substrate item supports, such as 206-2, may be designed with larger and/or a plurality of ledge feature(s) 207 or the like to provide support for two or more substrate items at a given horizontal substrate item level.

A first substrate item level 210-1 and a second substrate item level 210-2 are labeled in FIG. 2 to further illustrate how substrate item supports 206 and eventually (e.g., when loaded) substrate items 208 may be arranged between an upper surface 212 of dividing member 202-2 and a lower surface 214 of dividing member 202-3.

FIG. 2 also illustrates that certain substrate items, such as, e.g., substrate item 208-1 may be substantially planar in shape, and/or that certain substrate items, such as, e.g., substrate item 208-2 may be non-planar in shape. Further still, substrate item support 206-3 may include a ledge feature that is different than ledge feature 207 of substrate support 206-1 as may be beneficial to accommodate the non-planar shape of substrate item 208-2.

FIG. 2 further demonstrates that substrate item supports 206 may be positioned within a horizontal perimeter of the stack which may be beneficial as it may allow for an edge of a substrate item 208 to be at or near the edge of the stack 204 and/or closer to the inner surface of liner member 116 which may promote more efficient use of the gaseous materials within the reactor chamber.

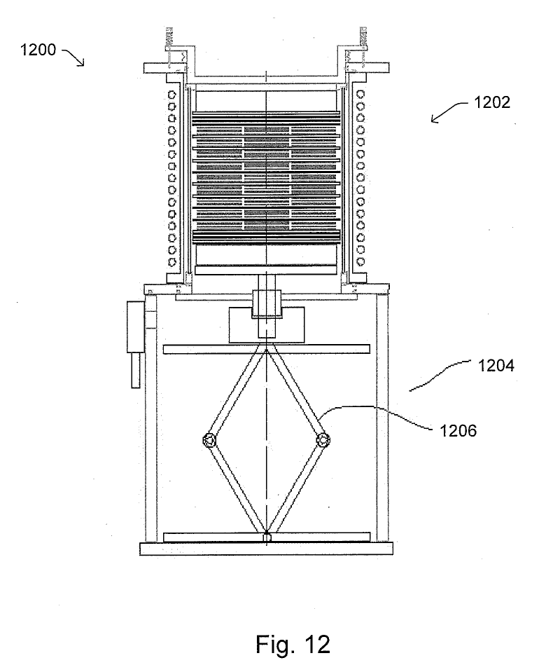

As illustrated in subsequent examples (e.g., FIG. 12) in certain implementations, two or more dividing members 202 may provided adjacent (or even abutting) one another within stack 204 without a substrate item support 206 and/or substrate item level there between. In certain implementations, two or more dividing members 202 may be provided which are different in some manner (e.g., different size, shape, thickness material, etc.).

In certain example implementations substrate item holding assembly 102 may include one or more thermal insulating members 222. For example, in certain implementations, a thermal insulating member 222 may be provided at or near the top, bottom, and/or at other locations within stack 204 as may be desired for certain designs. In certain implementations, thermal insulating members 222 may, for example, include disks of quartz, ceramic, zicor or other low thermal conductance materials, or disks of hollowed-out quartz with the interior at high vacuum, and/or the like. Those skilled in the art will recognize that connecting member 224, and/or another connecting mechanism (not shown) may be adapted to attach one or more thermal insulating members 222 to and/or within stack 204.

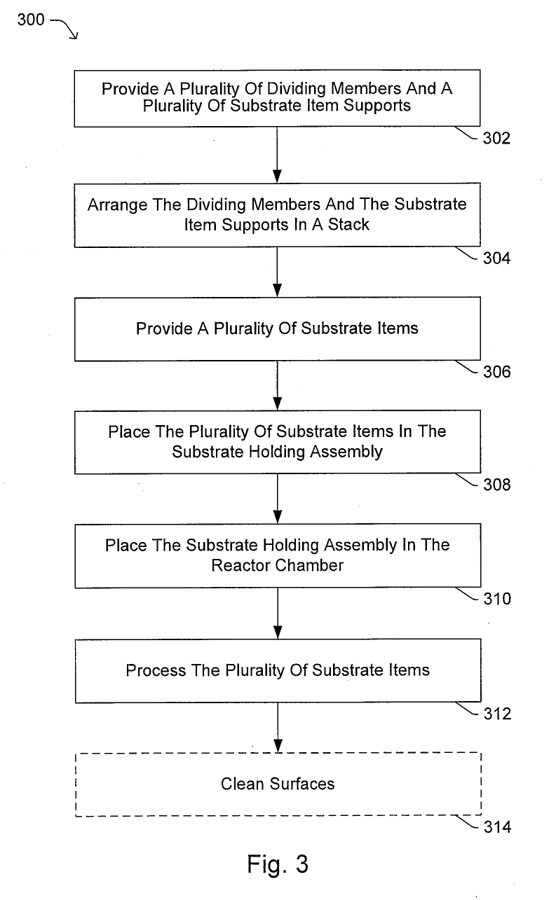

Attention is drawn next to FIG. 3, which is a flow diagram illustrating an exemplary method 300 that may be implemented, at least in part, for example, by system 100.

At block 302, at least a plurality of dividing members and a plurality of substrate item supports may be provided. At block 304, the dividing members and the substrate item supports may be arranged in a stack to form at least a portion of a substrate item holding assembly. For example, the substrate item supports may be arranged to extend from at least one of the dividing members to support at least two substrate items at a first level located between an upper surface of a first one of the plurality of dividing members and a lower surface of a second one of the plurality of dividing members.

At block 306 a plurality of substrate items may be provided and at block 308 at least two of the substrate items may be placed in the substrate holding assembly as arranged at block 304 such that at least the two substrate items are in contact with substrate item supports at a first level within the substrate item holding assembly. Block 306 and/or block 308 may, for example, include using one or more transport assemblies and/or portions thereof to move the substrate items and/or the substrate holding assembly.

At block 310, the substrate item holding assembly may be placed into a reaction chamber. Block 310 may, for example, include using one or more transport assemblies and/or portions thereof to move the at least partially loaded substrate holding assembly.

At block 312, the substrate items may be processed in some manner. For example, at least one layer of material may be established on at least a portion of the substrate items via a deposition and/or other like process within the reaction chamber. In other examples, an oxidation process may be conducted. In still other examples, a material removal process, etching process, and/or the like may be conducted. In certain implementations, a thermal cycling process and/or the like may be conducted. It should be recognized that, at block 312, one or more processes of various types may be conducted.

At block 314, which may be optional, one or more surfaces of the reaction chamber, substrate item holder, and/or (if needed) a gap region between a liner member and a sidewall member may be cleaned, for example, by establishing plasma. Here, for example, the rate of cleaning may be accelerated via the introduction of reactive gases such as NF₃. At appropriate temperatures, injecting the proper gas, HCl, for example, may provide cleaning (e.g., stripping) of Silicon, for example, without plasma.

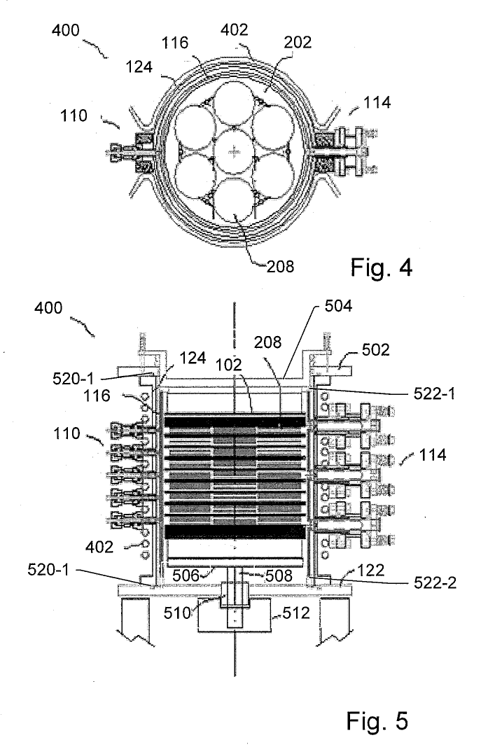

With the techniques as presented above in mind, attention is drawn next to several example implementations and features thereof which are illustrated in FIGS. 4-17.

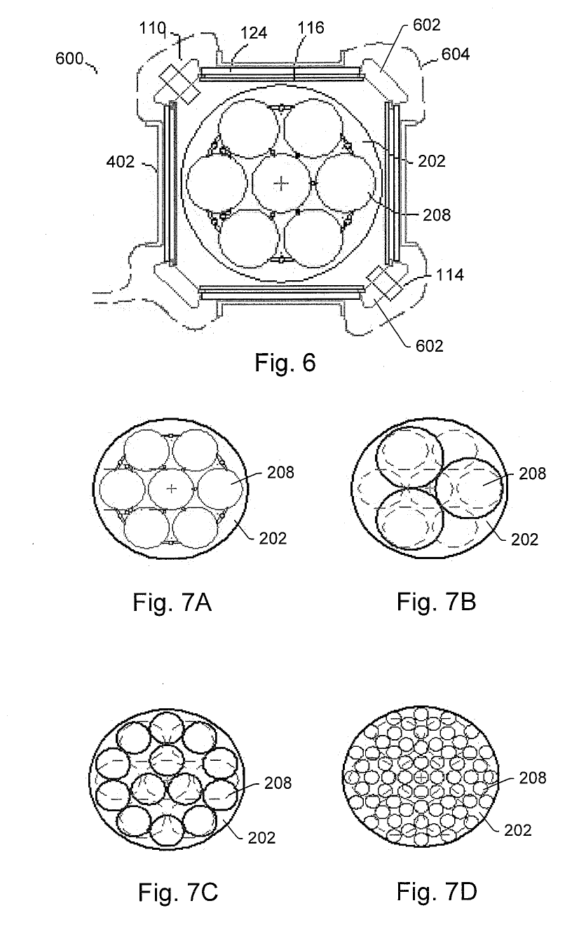

As described in greater detail in the subsequent sections, in certain example implementations, at least a portion of a reactor apparatus may include an insulating material such as quartz to permit the transmission of radiant and/or electromagnetic energy there through as desired to heat the interior. An example reactor apparatus 400 in FIGS. 4 and 5 includes, by way of example, quartz or other like material based sidewall member 124 that may be shaped as a cylinder. In certain implementations sidewall member 124 may represent part of a domed or other like shaped unitary piece. Another example reactor apparatus 600 in FIG. 6 includes, by way of example, several quartz walls or other like material to form a sidewall member 124 within a housing assembly that also include several metallic walls 602.

As illustrated in the cross-sectional top-view of FIG. 4, an example reactor apparatus 400 may include a liner member 116 within which may be placed a substrate item holding assembly represented here by dividing member 202 and substrate members 208. Sidewall member 124 may be spaced apart from and surround liner member 116. One or more induction coils 402 and/or other like heating mechanisms may be arranged near sidewall member 124. A portion of gas supply assembly 110 and a portion of gas exhaust assembly 114 may be provided and coupled to one or more of sidewall member 124 and/or liner member 116.

The cross-sectional side-view of selected portions of the example reactor apparatus 400 in FIG. 5 further illustrates an exemplary arrangement of substrate item holding assembly 102 within the housing assembly of reactor apparatus 400. Here, for example, such housing assembly may include a top plate 502, a top cover 504, sidewall member 124, and bottom member 122. The sidewall member 124 in this example may include a unitary piece of quartz or other like materials. For certain lower temperature processes, sidewall member 124 may include pyrex, ceramic or other material. For certain low temperature processes, heating elements (not shown) may be embedded or otherwise arranged in sidewall member 124. Here, for example, sidewall member 124 may comprise metal, such as, e.g., 200 C atomic layer deposition of Al2O3, and/or the like.

Sidewall member 124 may, for example, take the shape of a cylinder having flanges at the ends so that the reactor chamber may be sealed, for example, based at least in part on upper and lower sidewall sealing mechanisms 520-1 and 520-2, respectively. By way of example but not limitation, upper and lower sidewall sealing mechanisms 520-1 and 520-2 may include o-rings, gaskets, and/or the like, that are arranged to provide a seal with top plate 502 and bottom member 122.

Liner member 116 may be arranged within sidewall member 124 and spaced some distance to form a gap region there between. Liner member 116 may, for example, include a conductive material such as Silicon Carbide coated Graphite, or the like. Accordingly, in this example, one or more induction coils 402 may be arranged in close proximity to the outside of sidewall member 124. When alternating electrical current is passed through such coil(s) 124 the resulting electromagnetic field causes corresponding electrical current(s) to flow in liner member 116 and as such liner member 116 may, in response, heat up. In other example implementations, other heating techniques may be employed. For example, radiant heating from high temperature lamps and/or radiant coils may be used. In certain examples, a liner member and/or portion(s)/feature(s) thereof may be directly connected to a source of radio frequency signals, and/or alternating current or direct current electricity (e.g., via one or more conductors, via insulated vacuum feed-through, etc.) which may be used to generate plasma and/or heat within the reaction chamber and/or the gap region.

In certain implementations, the temperature distribution, e.g., up and down the vertical height of liner member 124, may be measured by one or more thermocouples, pyrometers, and/or other like sensors. In certain implementations, such temperature distribution information may be useful in controlling a process and/or controlling different induction coils 402 and/or other like heating elements, which may be arranged to control the temperature in certain regions. For example, separately controlled heating zones may be established for different regions and controlled using on closed-loop and/or model based control mechanisms. Certain exemplary reactor apparatuses may, for example, include a plurality of such heating zones.

In this example, the heated conductive liner member 124 may in turn transmit thermal energy to the substrate item holding assembly 102 (and substrate items therein) primarily via radiation at very low pressures or via radiation and/or convection in the case of higher pressures. As illustrated in this example, substrate item holding assembly 102 may include a plurality of dividing members arranged in a vertical stack with one or more horizontal levels defined by substrate item supports for holding a plurality of substrate items at each level. By way of example but not limitation, as shown in FIG. 4 the substrate items in this example implementation may include wafers, with seven wafers (e.g., one about the vertical axis of the stack surrounded by six others) arranged at each level, with four levels between applicable dividing members.

In certain implementations, to maintain desired temperatures, the top and/or bottom regions of the chamber may be maintained at temperatures elevated from the temperature of the central portion to make up for heat losses that may occur at one and/or both ends of substrate item holding assembly 102. This may occur, for example, due to top plate 504 and/or bottom member 122 being unheated. Thermal insulating members 222 (see FIG. 2) may be included for such purposes. In certain implementations additional dividing members may be provided in a stack near the top and/or bottom, for example, to provide additional thermal mass. In certain implementations one or more separate heaters (not shown) may be provided, e.g., nearer the top or bottom of the stack.

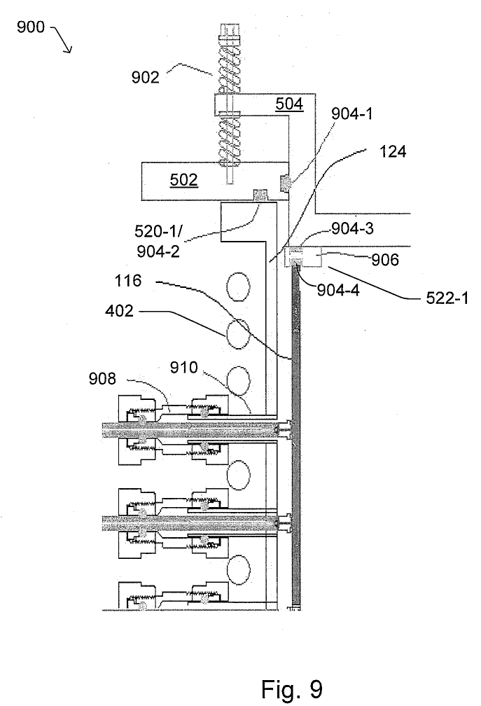

One or more openings may be formed in sidewall member 124 to allow for portions of gas supply assembly 110 and gas exhaust assembly 114 to extend through sidewall member 124, for example, on opposing sides. In certain implementations, for example, quartz or other applicable tubes 910 (e.g., see FIG. 9) may be provided (e.g., formed, welded or otherwise attached) to sidewall member 124 at the locations of the openings. Such tubes may, for example, extend out and away from the heat which may allow attachment of supply and or exhaust connections 908 (see, e.g., FIG. 9) via o-ring or other like sealing mechanisms.

Thus, with the arrangement illustrated in FIG. 5, gaseous materials may be made to flow horizontally between dividing members and through the various levels and across exposed surfaces of the substrate items as arranged in substrate item holding assembly 102. Here, in this example, substrate item holding assembly 102 may be attached to a support 506 which may be attached to a shaft 508 which may pass through a rotary feed-through 510 and may be connected to a rotation motor assembly 512. Thus, in this example, substrate item holding assembly 102 may be selectively/continuously rotated (e.g., perhaps slowly at about 2 to 10 RPM, or as otherwise deemed appropriate). Such rotation may provide for improved gaseous material flows and/or promote more uniform temperatures within the reaction chamber.

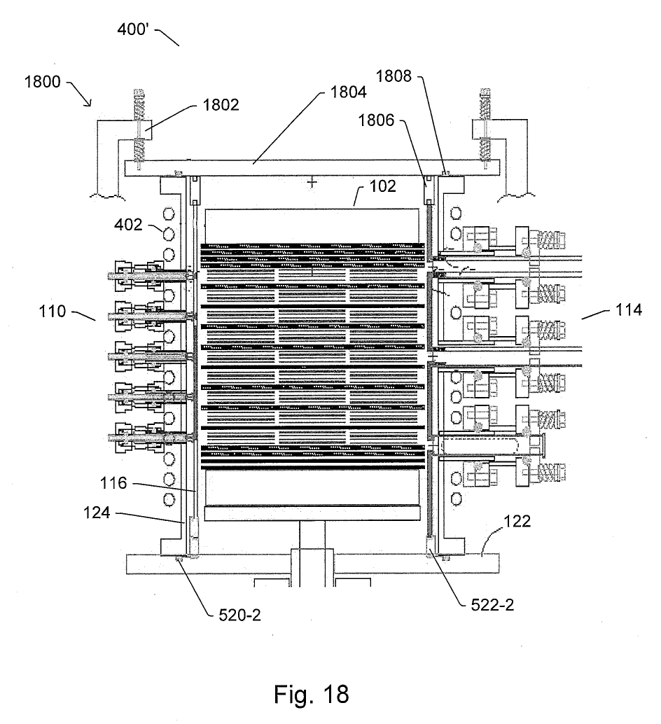

FIG. 18 is a cross-sectional side-view of selected portions of yet another example implementation of a reactor apparatus 400′, for example of FIG. 4. Here, as illustrated a housing assembly may include a top cover clamping member 1800 that is affixed at its lower end to bottom plate 122 or the machine's main frame (not shown) may include a top cover clamping ring 1802, with or without a constant force mechanism, and a top cover 1804. Here, unlike the example implementation in FIG. 5, top cover clamping ring 1802 (which is coupled to bottom member 122) is arranged above top cover 1804 and top cover 1804 may be adapted to be sealed to liner member 116 and/or sidewall member 124 or both, through upper liner sealing mechanism 1806 and upper sidewall sealing mechanism 1808, respectively.

Those skilled in the art will recognize that other designs may be implemented and that some may employ a top member having one or more pieces, that may be arranged in various ways and that various sealing mechanisms, and various fixing, compression and/or other like structural or connecting mechanisms may be used.

Attention is drawn next to FIG. 6, which illustrates, in a cross-sectional top-view, selected portions of another example reactor apparatus 600, having a similar substrate item holding assembly therein. In this example, sidewall member 124 may include four windows or plates that may be arranged between four walls 602. Such windows may be sealed to the walls using various sealing mechanisms such as, for example, o-rings, gaskets, or the like (not shown). Here, for example, walls 602 may comprise one or more metals, such as aluminum, stainless steel, or the like. Such metal walls may be cooled or temperature controlled via liquid flowing through channel(s), gun drilled holes, or the like, as is known in the art.

In this example, induction coils 402 or other heating element (e.g., radiant heaters, etc.) may be connected or otherwise arranged to provide one or more zones as illustrated by connection(s) 604. Here, liner members 116 may be provided and spaced apart from corresponding sidewall members 124.

The arrangement of substrate items 208 with respect to dividing members 202 may vary depending on need. FIGS. 7A-D are top-view diagrams illustrating exemplary arrangements of a plurality of different substrate items 208 arranged with respect to an exemplary dividing member 202 of a substrate item holding assembly. Thus, by way of example but not limitation, FIG. 7A shows seven 200 mm wafers per horizontal level, FIG. 7B, shows three 300 mm wafers, FIG. 7C shows thirteen 150 mm wafers, and FIG. 7D shows sixty four 65mm substrates (e.g., size of hard disks used in computer memory). Thus, for example, in an exemplary reactor chamber size where there are a total of 252 wafers (7 per level×4 level, ×9 spaces) of 200 mm diameter, more than 2,000 disks of 65 mm may be placed and processed. Such high packing density combined with minimizing expensive precursor gas waste may provide significant processing throughput and/or otherwise result in significant cost savings.

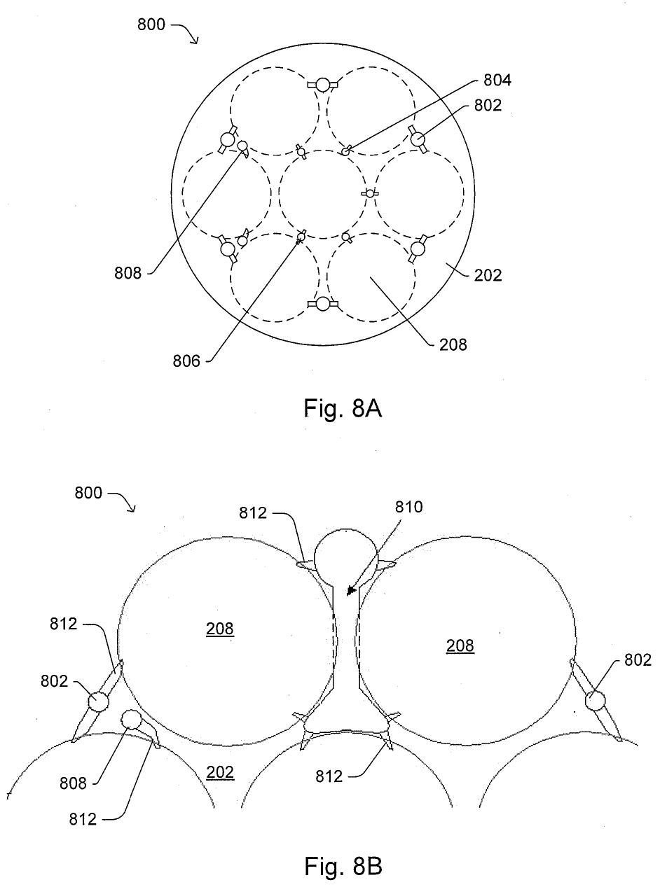

FIG. 8A is similar to FIG. 7A and shows a top-view diagram of an exemplary arrangement of a plurality of substrate item supports 802, 804, 806 and 808 extending from an exemplary dividing member 202 of a substrate item holding assembly. As shown, the substrate item supports may take on various forms and be configured to allow for loading and unloading of substrate items 208. Here, for example, substrate item support 802 may be adapted to support at least two substrate items at a given level, substrate item support 804 may be adapted to support one substrate item at the level, substrate item support 806 may be similar to substrate item support 802 but have more compact size (e.g., shorter ledges, etc.) to support two substrate items at the level, and substrate item support 808 may be adapted to support one substrate item at the level and to also have a shape or function that allows for the loading/unloading of the substrate item(s) nearer the center.

FIG. 8A illustrates that selected substrate item supports though which connecting members may extend may be located within interior regions of the substrate item holding assembly rather than at or nearer the edges as is the case with vertical wafer boats. Thus, the amount of susceptor overlap, if any, may be tailored to the process conditions. Hence, in certain implementations, a reduction in wasted gaseous materials may be realized as previously described.

FIG. 8B is a top-view diagram illustrating a portion of another exemplary arrangement of a plurality of substrate item supports 802, 808 and 810 of a substrate item holding assembly supporting substrate items 208. As illustrated in this example, substrate item support 810 may be adapted to provide support for a plurality of substrate items 208. As shown, example substrate item support 810 may provide a plurality of ledges 812 and/or other like support surfaces, points, etc. for a given substrate item. Furthermore, as shown In the examples presented in FIGS. 8A-B, in certain implementations it may be desirable for substrate item supports to provide support for each substrate item at three or more points.

Additionally, in certain implementations, a substrate item support need not include an opening for a connecting member to pass there through. Indeed, in certain implementations one or more connecting members may be employed which do not pass through and/or otherwise contact a substrate item support with or without one or more connecting members (e.g., structural rods, etc.) passing through it, can provide multiple points of support for multiple wafers.

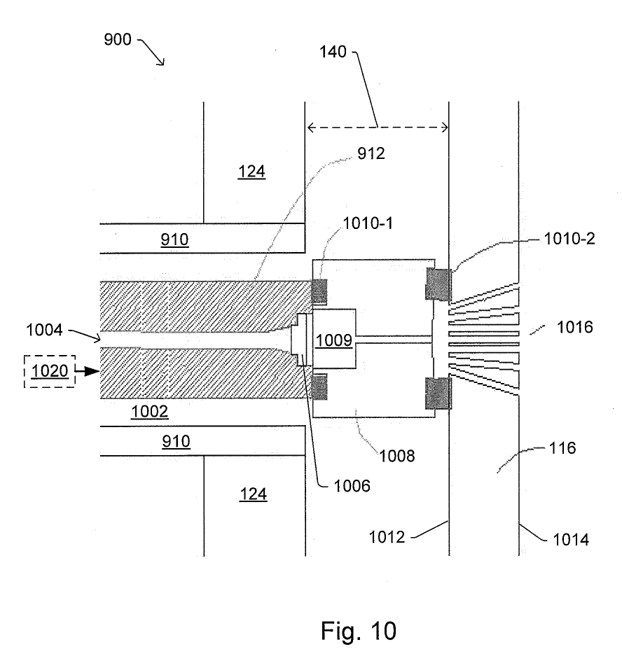

FIGS. 9 and 10 are close-up cross-sectional side-views of a selected portion of an example reactor apparatus 900. As illustrated, an exemplary gas inlet member 912 (see FIG. 10) portion of a gas supply assembly 110 may be arranged to pass through tubes 910 and openings 1002 of sidewall member 124 and couple to liner member 116.

FIG. 10 provides a closer view in which, in this example, gas inlet member 912 may be coupled to an outer surface 1012 of liner member 116 at a point wherein there may be at least one opening 1016 formed through liner member 116 to an inner surface 1014. In this example, gas inlet member 912 may be urged by a continuous force mechanism 1020 towards the outer surface 1012 of liner member 116. For example, a spring or constant pressure ram (not shown) may be used as continuous force mechanism 1020.

An injection adapter 1008 may be provided to couple gas inlet member 912 to liner member 116 and allow gaseous materials to pass through opening 1004 of gas inlet member 912 and opening 1009 of injection adapter 1008 and opening(s) 1016 of liner member 116. Injection adapter 1008 may be made from quartz, alumina or other such materials, for example. As shown, a sealing mechanism 1010-1 may be provided to establish a seal between gas inlet member 912 and injection adapter 1008, and a sealing mechanism 1010-2 may be provided to establish a seal between injection adapter 1008 and the outer surface 1012 of liner member 116. As shown in this example implementation, a counter-bore 1006 may be provided to hold the injection adapter 1008.

In certain example implementations, gas inlet member 912 may be made of metal, e.g. stainless steel, and/or made from insulating material such as alumina for example. Tube 910 may be made of quartz and connections 908 may include o-ring sealed using compression fittings (such as, e.g., Ultra-Torr™ fittings made by Swagelok Corporation). Sealing mechanisms 1010-1 and/or 1010-2 may include a compliant gasket or the like. For example, a compliant gasket may be made from known materials such as Viton or Calrez for low temperature applications or Graphoil or Sigraflex for high temperature processes.

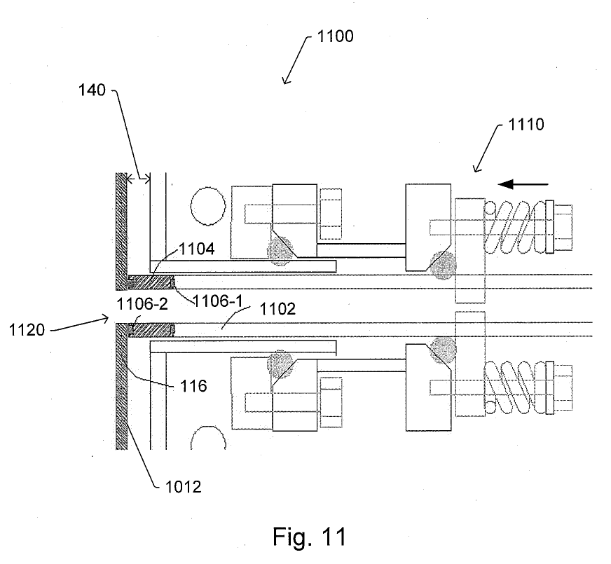

FIG. 11 provides a close view of a portion 1100 similar to FIG. 10, but with regard to an exemplary exhaust member 1102. Here, in this example, gas exhaust member 1102 is coupled to an outer surface 1012 of liner member 116 at a point wherein there is at least one exhaust opening 1120 formed through liner member 116. In this example, gas exhaust member 1102 may be urged by a continuous force mechanism 1110 towards the outer surface of liner member 116. An exhaust adapter 1104 may be provided to couple gas exhaust member 1102 to liner member 116 and allow gaseous materials to pass (e.g., be drawn) through the exhaust opening of liner member 116 and out through exhaust adapter 1104 and gas exhaust member 1102. Exhaust adapter 1104 may be made from quartz, alumina or other such materials, for example. As shown, a sealing mechanism 1106-1 may be provided to establish a seal between gas exhaust member 1102 and exhaust adapter 1104, and a sealing mechanism 1106-2 may be provided to establish a seal between exhaust adapter 1104 and the outer surface of liner member 116. Here, sealing mechanisms 1106-1 and/or 1106-2 may be made of similar materials as sealing mechanisms to 1010-1 and/or 1010-2.

Attention now returns to FIG. 9 which also illustrates certain exemplary housing assembly features. For example, FIG. 9 illustrates how top cover 504 may be sealed to top plate 502 (which may be in the form of a ring) via a top cover sealing mechanism 904-1, which may include an o-ring and/or the like which may allow top cover 504 to move with respect to top plate 502 while maintaining a seal. Further, an upper sidewall sealing mechanism 520-1 (here, including e.g., o-ring 904-2) may be arranged to seal top plate 502 and sidewall member 124. Additionally, an upper liner sealing mechanism 522-1 may be arranged to seal top cover 504 and liner member 116.

To reduce movement which may cause particles or fatigue of the gaskets when the chamber is pumped down or when an evacuated chamber is relieved to atmosphere, a constant force may be maintained by one or more appropriate continuous force mechanisms. In the example implementation of FIG. 9, continuous force mechanism 902 (represented here by a double spring arrangement) may be coupled to top plate 502 and the top cover and arranged to urge the top cover into contact with the top cover sealing mechanism, the top cover into contact with the upper liner sealing mechanism, the upper liner sealing mechanism into contact with the liner member, and the liner member into contact with the lower liner sealing mechanism. For example, top cover 504 may be urged downward by a continuous force mechanism 902 so as to compress a gasket 904-3 against an insulating ring 906 which in turn compresses a gasket 904-4 against the liner member 116.

In certain example implementations, gas (e.g., an inert gas) may be injected through one or more channels/holes (not shown) through top plate 502 (e.g., between o-rings 904-1 and 904-2) and/or sidewall member 124 in order to maintain a higher pressure in the gap region 140 between the liner member 116 and sidewall member 124 than the pressure within chamber 106. By maintaining such a pressure differential (e.g., approximately a 10 to 50 Torr difference) the gaseous materials in the chamber may be significantly prevented from entering gap region 140, which may reduce unwanted deposition of materials on one or more of the exposed surfaces within gap region 140. Such a pressure differential may reduce the chances of reactive gases from entering gap region 140 and becoming rather stagnant and/or reducing the potential for unwanted gas phase reactions. This is particularly the case where the compliant gaskets are fabricated from high temperature materials, such as, e.g., Graphoil, Sigraflex and the like due to their significantly higher permeability than that of typical o-ring materials such as Viton.

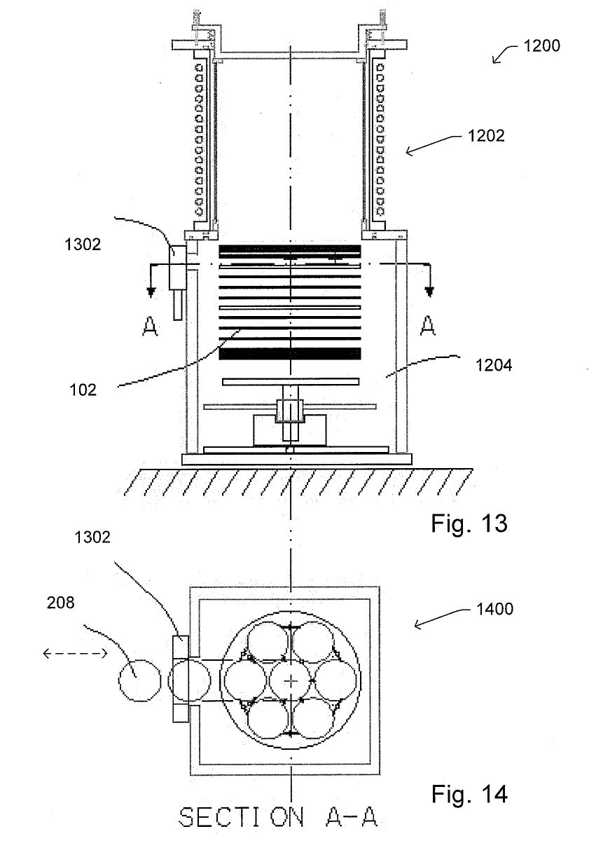

FIGS. 12 and 13 are cross-sectional side-views of selected portions of an example apparatus 1200 having a reaction chamber 1202 and a second chamber 1204. FIGS. 12 and 13 illustrate how an exemplary transport assembly 1206 (represented here by a scissor lift mechanism) may be used to move a substrate item holding 102 between reaction chamber 1202 and second chamber 1204. In FIG. 12 transport assembly 1206 has moved a loaded substrate item holding assembly 102 into reaction chamber 1202 and sealed reaction chamber 1202 with the bottom member contacting a lower sidewall member sealing mechanism. In FIG. 13 transport assembly 1206 has moved substrate item holding 102 from within reaction chamber 1202 to second chamber 1204 following unloading of substrate items from substrate item holding assembly 102. In this example, transport assembly 1206 may be selectively controlled to move substrate item holding assembly 102 to specific vertical positions within second chamber 1204 such that another transport assembly 1302 (represented here in part by an access port mechanism) may be employed to load/unload substrate items 208 to/from various levels within the stack. By way of example/representation, FIG. 14, which is a cross-sectional top view as cut-line A of FIG. 13 illustrates loading/unloading of substrate items 208 via the access port mechanism.

In certain implementations, such loading and unloading of substrate items may also employ selective rotation of substrate item holding assembly 102 by one or more other transport assemblies. In this example, second chamber 1204 may therefore serve, at least in part, as a substrate transfer chamber.

In many CVD, ALD, EPI, and/or other like processes/applications, the substrate items may be particularly sensitive to rapid temperature excursions, e.g., either due to materials, thicknesses, etc., which may allow the items to easily bend or warp, crack or break, and/or oscillate and possibly fall off of their supports/ledges. Thus, a slow ramp up or down in temperature may be beneficial to prevent or reduce these and/or other problems. Such ramping processes may represent a very significant part of an over-all process cycle time.

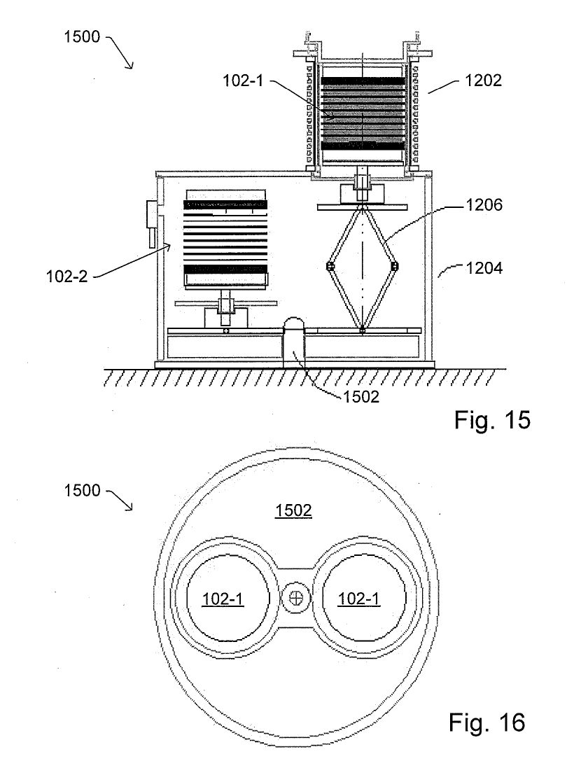

Accordingly, as shown in FIGS. 15 and 16 in certain example implementations, an apparatus 1500 having a reaction chamber 1202 and a large second chamber 1204 may be provided to accommodate a plurality of substrate item holding assemblies 102-1 and 102-2 which may be moved (e.g., rotated in this example) within second chamber 1204 by an exemplary transport assembly 1502 (represented here by rotating mechanism). In this example, substrate item holding assemblies 102-1 and 102-2 may each be associated with a separate transport assembly 1206, etc., for moving the substrate item holding assembly between reactor chamber 102 and second chamber 1204. Thus, in this example, while a desired process may be occurring in reactor chamber 102 with regard to substrate items within substrate item holding assembly 102-1, substrate items within substrate item holding assembly 102-2 may be allowed to ramp down or up in temperature (or a temperature maintained) within second chamber 1204 prior to unloading or other processing. FIG. 16 shows a cross-sectional top-view of apparatus 1500.

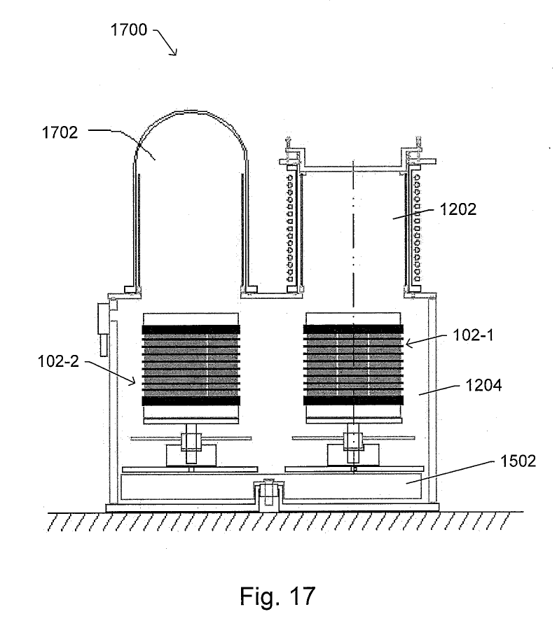

FIG. 17 illustrates a similar multiple chamber apparatus 1700 having a reaction chamber 1202, a large second chamber 1204, and also a third chamber 1702 that may be provided to accommodate a plurality of substrate item holding assemblies 102-1 and 102-2 which may be moved within second chamber 1204 by transport assembly 1502 and also moved into either reaction chamber 1202 or third chamber 1702. Third chamber 1702 may be adapted and/or used for a variety of purposes some examples of which follows. One example type of use may be for reactive ion, chemical vapor and/or other such techniques of cleaning and/or or surface treatment of the substrate items prior to (or following) a deposition or other like process in reactor chamber 1202. Another example may include pre-heating of substrate items, such as, e.g., wafers made of thermally fragile materials or very thin wafers which can easily warp causing cracks or other damage or causing the thin wafers to vibrate off their supports. Yet another example may be to deposit one type of film in reaction chamber 1202 and another material in third chamber 1702. In certain implementations, third chamber 1702 may even be the same or in other ways similar to reactor chamber 1202. Those skilled in the art will recognize, therefore, that a plurality of chambers may be provided and arranged with applicable transport assemblies and controllers to provide for sequential or parallel or a combination of sequential and parallel processing of substrate items.

While certain exemplary techniques have been described and shown herein using various methods and systems, it should be understood by those skilled in the art that various other modifications may be made, and equivalents may be substituted, without departing from claimed subject matter. Additionally, many modifications may be made to adapt a particular situation to the teachings of claimed subject matter without departing from the central concept described herein. Therefore, it is intended that claimed subject matter not be limited to the particular examples disclosed, but that such claimed subject matter may also include all implementations falling within the scope of the appended claims, and equivalents thereof.

What is claimed is:

1. An apparatus comprising:
a plurality of dividing members arranged in a stack; and
a plurality of substrate item supports extending from at least one of said plurality of dividing members, said plurality of substrate item supports to support at least two substrate items at a first level located between an upper surface of a first one of said plurality of dividing members and a lower surface of a second one of said plurality of dividing members.

2. The apparatus as recited in claim 1, wherein said plurality of substrate item supports support at least two other substrate items at a second level located between said first level and said lower surface of said second one of said plurality of dividing members.

3. The apparatus as recited in claim 1, wherein at least one of said plurality of substrate item supports provides support for at least said two substrate items at said first level.

4. The apparatus as recited in claim 1, wherein at least one of said plurality of substrate item supports provides at least two points of support for at least one of said two substrate items at said first level.

5. The apparatus as recited in claim 1, wherein at least three of said plurality of substrate item supports are arranged to provide support one of said at least two substrate items at said first level.

6. The apparatus as recited in claim 1, wherein said at least one of said plurality of substrate item supports is arranged to provide support a non-planar shaped substrate item.

7. A system comprising:
a substrate item holding assembly comprising:
a plurality of dividing members arranged in a stack; and
a plurality of substrate item supports extending from at least one of said plurality of dividing members, said plurality of substrate item supports to support at least two substrate items at a first level located between an upper surface of a first one of said plurality of dividing members and a lower surface of a second one of said plurality of dividing members; and
a housing assembly forming a sealable reaction chamber therein, said reaction chamber being opertively enabled to receive said substrate holding assembly.

8. The system as recited in claim 7, said reactor apparatus comprising:
a bottom member;
a sidewall member; and
a lower sidewall sealing mechanism arranged to seal said bottom member and said sidewall member together.

9. The system as recited in claim 8, wherein said sidewall member comprises a quartz chamber.

10. The system as recited in claim 8, said reactor apparatus further comprising:
at least one mechanism operatively enabled to couple said bottom member, with said lower sidewall sealing mechanism and said lower sidewall sealing mechanism with said sidewall member.

11. The system as recited in claim 10, wherein said at least one mechanism comprises a continuous force mechanism enabled to apply a pressure that at least acts to seal said bottom member with said sidewall member, at least in part, using said lower sidewall sealing mechanism.

12. The system as recited in claim 8, said reactor apparatus further comprising:
a top member comprising at least one of a top plate and/or a top cover, wherein at least a portion of said member is coupled to said bottom member; and
an upper sidewall sealing mechanism arranged to seal at least one of said top plate and/or said top cover top plate with said sidewall member.

13. The system as recited in claim 12, wherein said top member comprises said top plate and said top cover, said reactor apparatus further comprising:
a top cover sealing mechanism arranged to seal said top plate and said top cover together and allow said top cover to move relative to said top plate while remaining sealed.

14. The system as recited in claim 12, said reactor apparatus further comprising:
a liner member;
an upper liner sealing mechanism arranged to seal at least one of said top plate and/or said top cover with said liner member; and
a lower liner sealing mechanism arranged to seal said bottom member and said liner member together.

15. The system as recited in claim 14, said reactor apparatus further comprising:
a continuous force mechanism coupled to at least one of said top plate and/or said top cover and operatively enabled to apply pressure to urge at least one of said top plate and/or said top cover into contact with said upper liner sealing mechanism, said upper liner sealing mechanism into contact with said liner member, and said liner member into contact with said lower liner sealing mechanism.

16. The system as recited in claim 14, wherein said liner member is operatively enabled to generate thermal energy in response to at least one electrical signal and/or electric current.

17. The system as recited in claim 14, wherein at least a portion of said sealable reaction chamber is formed between an inner surface of said liner member, a lower surface of at least one of said top plate and/or said top cover and an upper surface of said bottom member.

18. The system as recited in claim 14, wherein at least a portion of a gap region is formed between an outer surface of said liner member and an inner surface of said sidewall member.

19. A method comprising:
providing a substrate item holding assembly comprising a plurality of dividing members arranged in a stack and a plurality of substrate item supports extending from at least one of said plurality of dividing members, said plurality of substrate item supports to support at least two substrate items at a first level located between an upper surface of a first one of said plurality of dividing members and a lower surface of a second one of said plurality of dividing members; and
placing said at least two substrate items in contact with said plurality of substrate item supports at said first level within said substrate item holding assembly.

20. The method as recited in claim 19, further comprising:
placing said substrate item holding assembly into a reaction chamber; and
processing at least said at least two substrate items within said reaction chamber.

21. The method as recited in claim 20, wherein processing at least said at least two substrate items within said reaction chamber comprising at least one of:
establishing at least one layer of material on at least a portion of said at least two substrate items;
removing material from said at least two substrate items,
etching an exposed surface of said at least two substrate items,
thermal cycling said at least two substrate items, and/or
establishing oxidation of at least a part of at least two substrate items.

22. The method as recited in claim 20, further comprising:
placing said substrate item holding assembly in at least one other chamber.

23. The method as recited in claim 19, wherein said plurality of substrate item supports support at least two other substrate items at a second level located between said first level and said lower surface of said second one of said plurality of dividing members.

24. The method as recited in claim 19, wherein at least one of said plurality of substrate item supports provides support for at least said two substrate items at said first level.

25. The method as recited in claim 19, wherein at least three of said plurality of substrate item supports are arranged to provide support one of said at least two substrate items at said first level.

26. The method as recited in claim 19, wherein said at least one of said plurality of substrate item supports is arranged to provide support a non-planar shaped substrate item.
